(19) United States
(12) Patent Application Publication
(10) Pub. No.: US 2009/0116083 A1
(43) Pub. Date: May 7, 2009

(54) IMAGE READING APPARATUS AND IMAGE READING METHOD

(75) Inventor: Masanori YOSHIZAWA, Hachioji-shi (JP)

Correspondence Address: BUCHANAN, INGERSOLL & ROONEY PC, POST OFFICE BOX 1404, ALEXANDRIA, VA, 22313-1404, US

(73) Assignee: KONICA MINOLTA BUSINESS TECHNOLOGIES, INC., Chiyoda-ku (JP)

(21) Appl. No.: 12/261,604

(22) Filed: Oct. 30, 2008

(30) Foreign Application Priority Data
Nov. 1, 2007 (JP) 2007-285134

(51) Int. Cl. H04N 1/46; G03F 3/08

(52) U.S. Cl. 358/505; 358/518

(57) ABSTRACT

An image reading apparatus comprises: a first reading unit for reading a first surface image of a document; a second reading unit for reading a second surface image of the document; and a color conversion processing unit for generating a table used for correcting an error of a read color of an image read by the first reading unit and an image read by the second reading unit, and performing a color conversion to the image read by said first reading unit and/or the image read by said second reading unit using the table.

### BACKGROUND OF THE INVENTION

1. Field of the Invention

The present invention relates to an image reading apparatus of a scanner, and so on, and for details, relates to an image reading apparatus and an image reading method performing a color conversion to a read image.

2. Description of Related Art

A reading unit for reading an image of a document includes a light source for irradiating light to the document and a solid state image pickup device for converting quantity of light of reflection light reflected by a document image to electric signals as main components.

It is well known that it is possible to read both sides of the document simultaneously by arranging two reading units in both sides of the document as a pair of reading units (hereinafter, a reading unit for reading a first surface of the document is called a first reading unit, and a reading unit for reading a second surface of the document is called as a second reading unit).

When the image reading apparatus reads a double-sided document, the difference of reading characteristic of the first reading unit and the second reading unit occur by the difference of structures of the first reading unit and the second reading unit or the difference of optical systems at the time of the assembly. As a result, for example, when two in one printing for printing both sides of the document on one page is performed, the problem of bad printing of appearance arises because a density difference occurs as to a right image and a left image.

Therefore, the technology for avoiding the difference between the reading characteristics of the first reading unit and the second reading unit is disclosed (see Japanese Patent Laid-Open No. 2005-20224, hereinafter referred to as Patent document 1).

The patent document 1 discloses to simply match gradations read by the first reading unit and the second reading unit respectively using a gradation correction or a color correction. That is, in an example of the patent document 1, one of the first reading unit and the second reading unit is matched with the other one of the second reading unit and the first reading unit to avoid generating the difference of the reading characteristics of the first reading unit and the second reading unit with respect to gradations.

### SUMMARY OF THE INVENTION

However, the patent document 1 fails to disclose a unit for matching colors between the first reading unit and the second reading unit. Also, when one of the first reading unit and the second reading unit is matched with the other one, there is possibility that the problem of making the color difference large in comparison with the document arises. That is, when the correction to match the reading characteristics of the second reading unit to the reading characteristics of the first reading unit is performed, there is possibility that the difference between the corrected image and the image of the second surface of the document becomes large in comparison with the difference between the image before correction and the image of the second surface of the document.

It is, therefore, a main object of the present invention to reduce color difference between a document and read images occurred by the differences of the reading characteristics of the first reading unit and the second reading unit.

In accordance with a first aspect of the present invention to achieve the object, an image reading apparatus comprises:

a first reading unit for reading a first surface image of a document;

a second reading unit for reading a second surface image of the document; and

a color conversion processing unit for generating a table for correcting an error of a read color of an image read by the first reading unit and an image read by the second reading unit, and performing a color conversion to the image read by the first reading unit and/or the image read by the second reading unit using the table.

Also, it is preferable that the color conversion processing unit generates a table for matching data read by the second reading unit to data read by the first reading unit based on the read data obtained by reading a chart for correction including a color gamut representable by the color converting processing unit by the first reading unit and the read data obtained by reading the chart for correction by the second reading unit, and performs the color conversion to the image read by the second reading unit based on the generated tale.

Also, it is preferable that the color conversion processing unit generates a table for matching data read by the first reading unit to data read by the second reading unit based on the read data obtained by reading a chart for correction including a color gamut representable by the color converting processing unit by the first reading unit and the read data obtained by reading the chart for correction by the second reading unit, and performs the color conversion to the image read by the first reading unit based on the generated tale.

Also, it is preferable that the color conversion processing unit generates a first table for the first reading unit based on the read data obtained by reading a chart for correction including a color gamut representable by the color converting processing unit by the first reading unit and the read data corresponding to the chart for correction, generates a second table for the second reading unit based on the read data obtained by reading the chart for correction by the second reading unit and the read data corresponding to the chart for correction, performs the color conversion to the image read by the first reading unit based on the first table, and performs the color conversion to the image read by the second reading unit based on the second table.

Also, it is preferable that the table is a color correction table for correcting the error of the read color of the image read by the first reading unit and the image read by the second reading unit and a table for converting inputted RGB data to corrected RGB data.

Also, it is preferable that the color conversion processing unit further includes a color conversion table for converting the corrected RGB data to YMCK data.

In accordance with a second aspect of the present invention to achieve the object, an image reading method in an image reading apparatus comprising a first reading unit for reading a first surface image of a document and a second reading unit for reading a second surface image of the document, the method comprising the steps of:

generating a table for correcting an error of a read color of an image read by the first reading unit and an image read by the second reading unit; and

performing a color conversion to the image read by the first reading unit and/or the image read by the second reading unit using the table.

Also, it is preferable that the image reading apparatus comprises an image reading unit for performing a centralized control of the image reading apparatus,

the generating step generates a table for matching data read by the second reading unit to data read by the first reading unit based on the read data obtained by reading a chart for correction including a color gamut representable by the color converting processing unit by the first reading unit and the read data obtained by reading the chart for correction by the second reading unit, and

the color conversion performing step performs the color conversion to the image read by the second reading unit based on the generated tale.

Also, it is preferable that the image reading apparatus comprises an image reading unit for performing a centralized control of the image reading apparatus,

the generating step generates a table for matching data read by the first reading unit to data read by the second reading unit based on the read data obtained by reading a chart for correction including a color gamut representable by the color converting processing unit by the first reading unit and the read data obtained by reading the chart for correction by the second reading unit, and

the color conversion performing step performs the color conversion to the image read by the first reading unit based on the generated tale.

Also, it is preferable that the image reading apparatus comprises an image reading unit for performing a centralized control of the image reading apparatus,

the generating step generates a first table for the first reading unit based on the read data obtained by reading a chart for correction including a color gamut representable by the color converting processing unit by the first reading unit and the read data corresponding to the chart for correction, generates a second table for the second reading unit based on the read data obtained by reading the chart for correction by the second reading unit and the read data corresponding to the chart for correction, and

the color conversion performing step performs the color conversion to the image read by the first reading unit based on the first table, and performs the color conversion to the image read by the second reading unit based on the second table.

Also, it is preferable that the table is a color correction table for correcting the error of the read color of the image read by the first reading unit and the image read by the second reading unit and a table for converting inputted RGB data to corrected RGB data.

Also, it is preferable that the image reading apparatus comprises an image reading unit for performing a centralized control of the image reading apparatus, wherein the color conversion processing unit further includes a color conversion table for converting the corrected RGB data to YMCK data.

In accordance with the first aspect and the second aspect of the present invention, it is possible to reduce the color difference occurred by the reading characteristics of the first reading unit and the second reading unit.

### BRIEF DESCRIPTION OF THE DRAWINGS

The above and other objects, advantages and features of the present invention will become more fully understood from the detailed description given below and the appended drawings, and the following descriptions pertain to the embodiment of the present invention are not intended to limit the present invention, and wherein:

FIG. 1 is a functional block diagram in the embodiment relating to the present invention;

FIG. 2 is a flowchart schematically showing a flow of a color conversion process for matching the reading characteristics of a second reading unit to the reading characteristics of a first reading unit, which is performed by a color conversion processing unit in FIG. 1;

FIG. 3 is a drawing schematically showing a chart to be read by the first reading unit and the second reading unit in FIG. 1;

FIG. 4 is a flowchart for performing a 3D-LUT decision process for preparing 3D-LUT to be used in the color conversion process in FIG. 2;

FIG. 5 is a flowchart schematically showing a flow of the color conversion process for matching the reading characteristics of the first reading unit to the reading characteristics of the second reading unit, which is performed by the color conversion processing unit in FIG. 1;

FIG. 6 is a flowchart for performing the 3D-LUT decision process for preparing 3D-LUT to be used in the color conversion process in FIG. 5;

FIG. 7 is a flowchart schematically showing a flow of the color conversion process for matching the reading characteristics of the first reading unit and the reading characteristics of the second reading unit to the reading characteristics of a flatbed, which is performed by the color conversion processing unit in FIG. 1;

FIG. 8 is a flowchart for performing the 3D-LUT decision process for preparing 3D-LUT to be used in the color conversion process in FIG. 7; and

FIG. 9 is a chart showing a combination of compositions of the first reading unit and the second reading unit.

### DESCRIPTION OF THE PREFERRED EMBODIMENTS

In the following, the best mode for carrying out an image reading apparatus of the present invention will be described in detail with respect to compositions and operations with reference to the drawings. It should be noted that the scope of the invention is not limited to the illustrated embodiments.

### First Embodiment

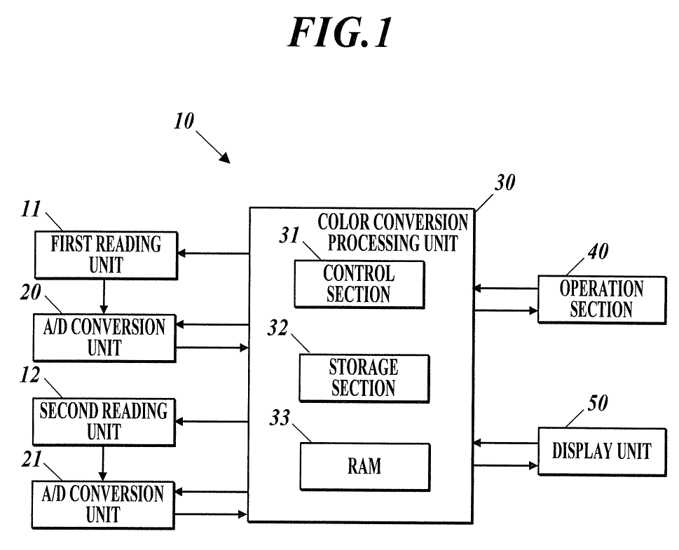

FIG. 1 is a block diagram showing main functional compositions of an image reading apparatus 10.

As shown in FIG. 1, the image reading apparatus 10 is composed of a first reading unit 11, a second reading unit 12, A/D conversion units 20 and 21, a color conversion processing unit 30, an operation unit 40, a display unit 50, and so on.

The first reading unit 11 is composed of CCD (Charge Coupled Devices), and so on not shown in Figures, and reads a first surface of a document. The second reading unit 12 is composed of CIS (Contact Image Sensor), and so on, and reads a second surface of the document. The first reading unit 11 and the second reading unit 12 output image signals (analog signals of R, G and B) of the read document images to the A/D conversion units 20, 21 respectively.

The A/D conversion units 20, 21 convert the analog signals inputted from the first reading unit 11 and the second reading unit 12 respectively to predetermined digital image signals (RGB data), and output it to the color conversion processing unit 30.

The color conversion processing unit 30 is composed of a control unit 31, a storage unit 32, RAM (Random Access Memory) 33, and so on.

The control unit 31 includes CPU (Central Processing Unit). The control unit 31 reads control programs stored in the storage unit 32, develops it to the work areas in the RAM 33, and performs a centralized control of each unit of the image reading apparatus 10 according to the developed programs.

Also, the control unit 31 reads various kinds of programs stored in the storage unit 32, develops it to the work areas in the RAM 33, and performs various processes such as 3D-LUT (3Dimentional-Look Up Table) color conversion process or 3D-LUT decision process, and so on which are mentioned later according to the developed programs.

The storage unit 32 is composed of a non-volatile semiconductor memory, and so on, and stores various kinds of control programs, various kinds of processing programs which are performed by the control unit 31, and parameters or data necessary for performing these programs. For example, the storage unit 32 stores a 3D-LUT 60 and a 3D-LUT 61 used by a color conversion process mentioned later. The 3D-LUT 60 is a table for converting RGB data to CMYK data. The 3D-LUT 61 is a table for matching the reading characteristics of the second reading unit 12 to the reading characteristics of the first reading unit 11 as mentioned later.

That is, 3D-LUT 61 is a color correction table for correcting the error of the read color of the image read by the first reading unit 11 and the image read by the second reading unit 12 and a table for matching colors of the read image of the first surface of the document and colors of the read image of the second surface of the document.

The RAM 33 has storage areas for temporarily storing the various kinds of programs, input or output data and parameters, and so on read from the storage unit 32 in the various kinds of processes to be performed and controlled by the control unit 31.

The operation unit 40 has various kinds of function keys such as a start key for instructing image reading, and so on, and outputs corresponding control signals to the control unit 31 when these function keys are operated.

The display unit 50 has a LCD (Liquid Crystal Display), and displays various kinds of operation screens for operating color conversion processes on the LCD.

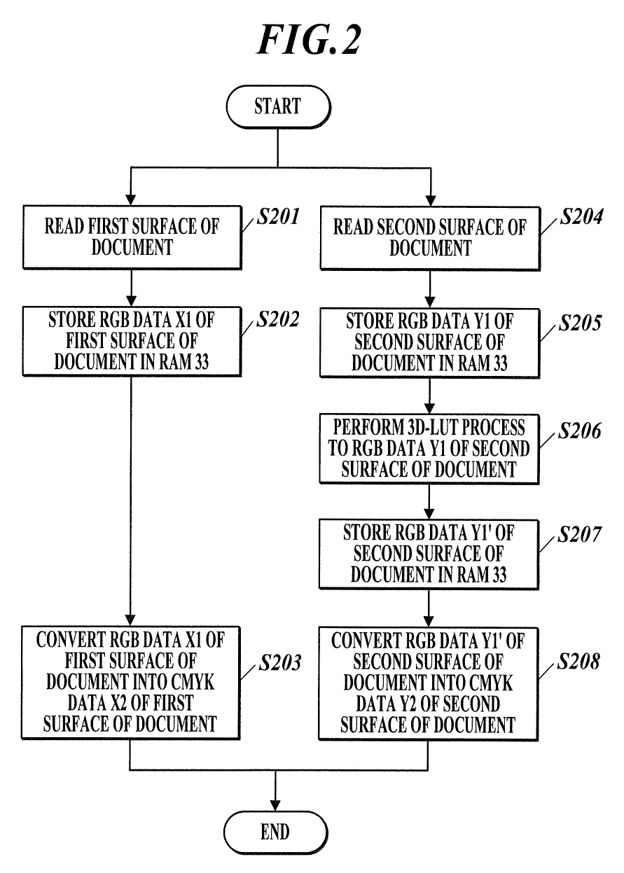

FIG. 2 schematically shows a flow of processes 3D-LUT color conversion process P1 to be performed by the color conversion processing unit 30. The first reading unit 11 reads a first surface of a document, the second reading unit 12 reads a second surface of the document almost simultaneously with performing the color conversion process of the first surface of the document and performs the color conversion process of the second surface of the document is performed.

The 3D-LUT color conversion process P1 is realized by a software process in cooperation with the control unit 31 and the program stored in the storage unit 32 when inputting an image reading instruction by the operation unit 40.

In the 3D-LUT color conversion process P1, a correction for matching the reading characteristics of the second reading unit 12 to the reading characteristics of the first reading unit 11.

First, processes of read data of the first surface of the document read by the first reading unit 11 will be described. The first surface of the document is read by the first reading unit 11, and the first surface RGB data X1 of the document is obtained (step S201). Next, an image process of a gamma correction, and so on for correcting color difference between colors represented by read data of first reading unit 11 and colors of the first surface of the document is performed to the first surface RGB data X1 obtained in step S201, and stored in the RAM 33 (step S202). Sequentially, the first surface RGB data X1 of document is converted to the first surface CMYK data X2 of the document by the 3D-LUT 60 prestored in the storage unit 32 (step S203).

Here, the 3D-LUT conversion to be performed by the color conversion processing unit 30 will be described.

The 3D-LUT conversion is a color conversion to be performed using the 3D-LUT when there is no linear relationship between input value and output value.

Correct colorimetry values can be obtained from RGB data by storing colorimetry values corresponding to RGB data one to one in a table, and so on as to all colors. However, in this method, it is not realistic because a huge memory space is needed. Therefore, the color conversion processing unit 30 prestores RGB data of a document chart colored by representative colors and colorimetry values in the 3D-LUT. The colorimetry values are obtained from RGB data by a three-dimensional interpolation in view of each point in the 3D-LUT.

Next, processes of read data of the second surface of the document read by the second reading unit 12 will be described. The processes explained below are performed almost simultaneously with the processes of the read data of the first surface of the document explained previously.

First, the second surface of the document is read by the second reading unit 12, second surface RGB data Y1 of the document is obtained (step S204). Next, the second surface RGB data Y1 obtained in step S204 is stored in the RAM 33 (step S205)

Then, the second surface RGB data Y1 of the document is converted to the second surface RGB data Y1′ of the document by 3D-LUT 61 prestored in the storage unit 32 (step S206), and stored in the RAM 33 (step S207). In addition, the 3D-LUT 61 to be used in step S206 is prepared by 3D-LUT decision process P2 mentioned later. Then, the second surface RGB data Y1′ of the document is converted to the second surface CMYK data Y2 by the 3D-LUT 60 prestored in the storage unit 32 (step S208).

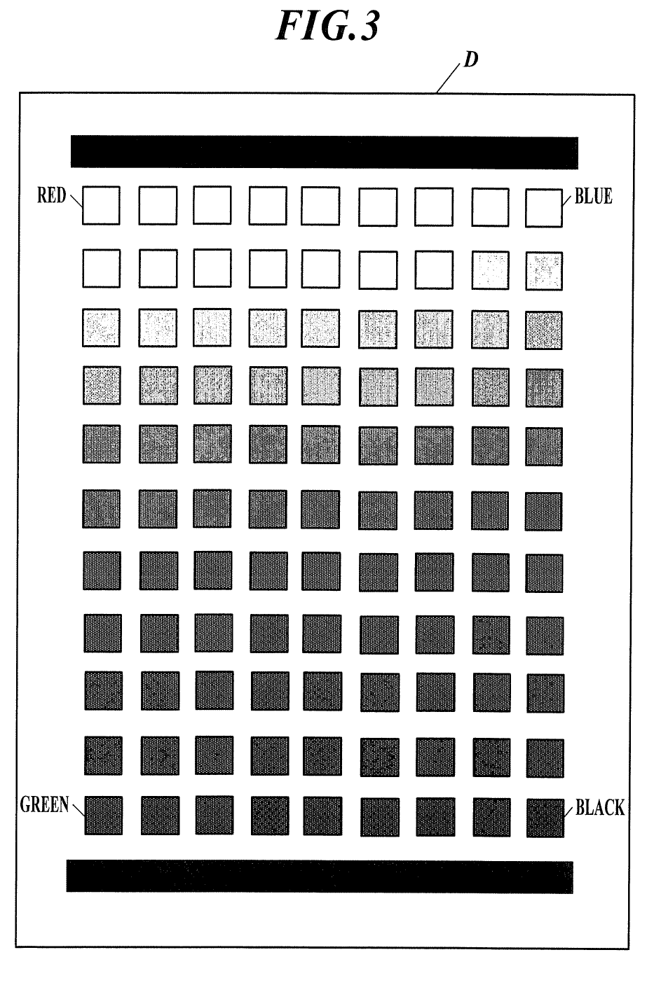

FIG. 3 is an example of a document chart D to be used in 3D-LUT decision process mentioned later. In the 3D-LUT decision process, the document chart D including color gamut representable by the color conversion processing unit 30 is used. When the color conversion processing unit 30 can represent RGB color space of 24 bits, because 16,777,216 colors can be covered, the document chart D including a color patch of colors selected by a user from these colors is considered. For example, as shown in FIG. 3, the chart including the red portion, green portion, blue portion, and black portion is used.

The number of color patches can be set to large or small number in comparison with an example shown in FIG. 3.

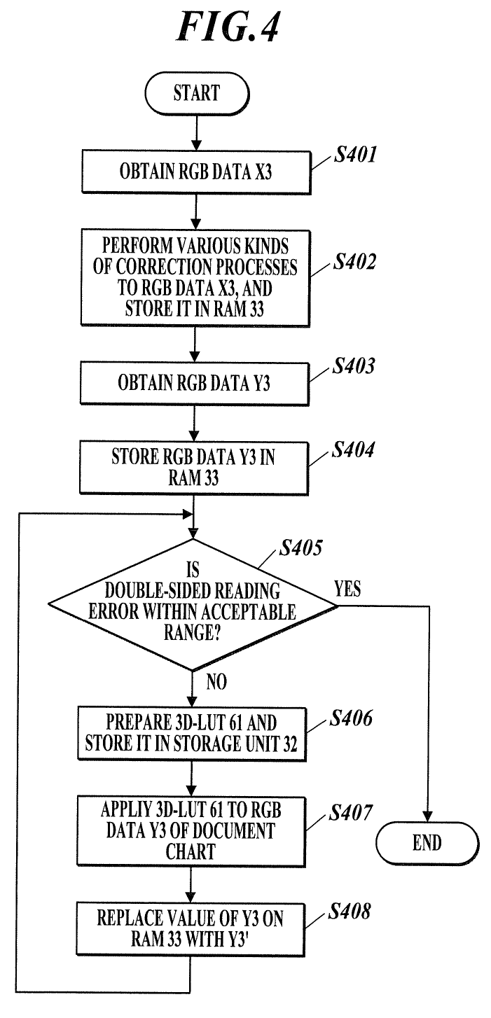

FIG. 4 shows the 3D-LUT decision process P2 to be performed by the color conversion processing unit 30.

The 3D-LUT decision process P2 is realized by a software process in cooperation with the control unit 31 and the program stored in the storage unit 32 when inputting a preparing instruction of 3D-LUT by the operation unit 40.

In the 3D-LUT decision process P2, 3D-LUT 61 to be used in step 206 of the 3D-LUT color conversion process P1.

First, the first reading unit 11 reads the document chart D, and RGB data X3 is obtained (step S401). Next, an image process of the gamma correction, and so on for correcting color difference between colors represented by read data of the first reading unit 11 and colors of the document chart D is performed to RGB data X3 obtained in step S401 and stored in the RAM 33 (step S402).

In the same manner, the second reading unit 12 reads the document chart D, and RGB data Y3 is obtained (step S403). Next, RGB data Y3 is stored in the RAM 33 (step S404).

Sequentially, the differences (hereinafter referred to as double-sided reading error) between RGB data X3 and RGB data Y3 are compared with the predetermined acceptable values (step S405). The acceptable values are variable and inputted by the operation unit 40, and the values are stored in the storage unit 32.

When the double-sided reading error is not within the range of the acceptable value (step S405; No), the 3D-LUT 61 is prepared so that RGB data Y3 approaches RGB data X3, and stored in the storage unit 32 (step S406).

Here, a preparing method of the 3D-LUT will be described. First, RGB data of the document chart D read by the first reading unit 11 or second reading unit 12 are distributed to a three dimensional RGB signal space and a colorimetry value space respectively. A RGB three dimensional space is divided in the lattice state, the 3D-LUT is prepared with respect to colorimetry values corresponding to rough lattice points of the input signal space by extrapolating points of three dimensional colorimetry value space corresponding to values of RGB on the lattice points.

Next, the 3D-LUT process is performed to the RGB data Y3 using the 3D-LUT 61 prepared in step S406 (step S407). In step S404, the value of RGB data Y3 stored in RAM 33 is replaced with RGB data Y3′ obtained in step S407 (step S408), and the step move to step S405.

The double-sided reading error is not more than the acceptable value (step S405; YES), the process is ended.

Thus, it is possible to obtain the 3D-LUT 61 for correcting the difference of the reading characteristics of the first reading unit 11 and the second reading unit 12 by the 3D-LUT decision process P2. The 3D-LUT 61 is used in step S206 of the 3D-LUT color conversion process P1.

Also, in step S402, the color difference between colors represented by read data of the first reading unit 11 and colors of the document chart D are corrected, the correction is performed using the 3D-LUT 61 prepared based on the corrected data. As a result, the problem of making color difference large in comparison with the document when one of the first reading unit and the second reading unit is matched with the other one is solved.

### Second Embodiment

Next, the second embodiment of the present invention will be described. In addition, since the components of the image reading apparatus 10 in the second embodiment is almost same with the components explained in the first embodiment, the explanations are incorporated, and different portions are explained below.

The storage unit 32 is different from the first embodiment because 3D-LUT 62 to be used in a color conversion process mentioned later is stored. The 3D-LUT 62 is a table for matching the reading characteristics of the first reading unit 11 to the reading characteristics of the second reading unit 12. The detailed explanations are mentioned later.

That is, 3D-LUT 62 is a color correction table for correcting the error of the read color of the image read by the first reading unit 11 and the image read by the second reading unit 12 and a table for matching colors of the read image of the first surface of the document and colors of the read image of the second surface of the document.

In the first embodiment, though the method for matching the reading characteristics of the second reading unit 12 to the reading characteristics of the first reading unit 11 is explained, in the second embodiment, the reading characteristics of the first reading unit 11 are matched to the reading characteristics of the second reading unit 12.

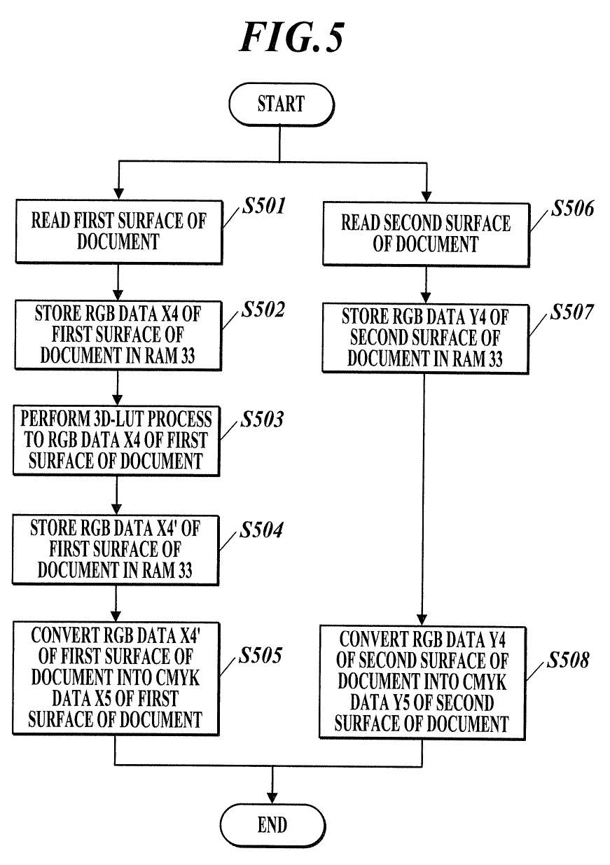

FIG. 5 schematically shows a flow of processes of the 3D-LUT color conversion process P3 to be performed by the color conversion processing unit 30. The first reading unit 11 reads the first surface of a document, and the second reading unit 12 reads a second surface of the document almost simultaneously with performing the color conversion process of the first surface of the document and performs the color conversion process of the second surface of the document.

The 3D-LUT color conversion process P3 is realized by a software process in cooperation with the control unit 31 and the program stored in the storage unit 32 when inputting an image reading instruction by the operation unit 40.

First, processes of read data of the first surface of the document read by the first reading unit 11 will be described. The first surface of the document is read by the first reading unit 11, and the first surface RGB data X4 of the document is obtained (step S501). Next, the first surface RGB data X4 of the document obtained in step S501 is stored in the RAM 33 (step S502).

Then, the first surface RGB data X4 of the document is converted to the first surface RGB data X4′ of the document by the 3D-LUT 62 (step S503), and stored in the RAM 33 (step S504). In addition, the 3D-LUT 62 to be used in step S503 is prepared by 3D-LUT decision process P4 mentioned later. Then, the first surface RGB data X4′ of the document is converted to the first surface CMYK data X5 of the document by the 3D-LUT 60 prestored in the storage unit 32 (step S505).

Next, processes of read data of the second surface of the document read by the second reading unit 12 will be described. The processes explained below are performed almost simultaneously with the processes of the read data of the first surface of the document explained previously.

First, the second surface of the document is read by the second reading unit 12, second surface RGB data Y4 of the document is obtained (step S506). Next, an image process of the gamma correction, and so on for correcting color difference between colors represented by the second reading unit 12 and colors of the second surface of the document is performed to the second surface RGB data Y4 of the document obtained in step S506, and stored in the RAM 33 (step S507).

Then, the second surface RGB data Y4 of the document is converted to the second surface CMYK data Y5 by the 3D-LUT 60 prestored in the storage unit 32 (step S508).

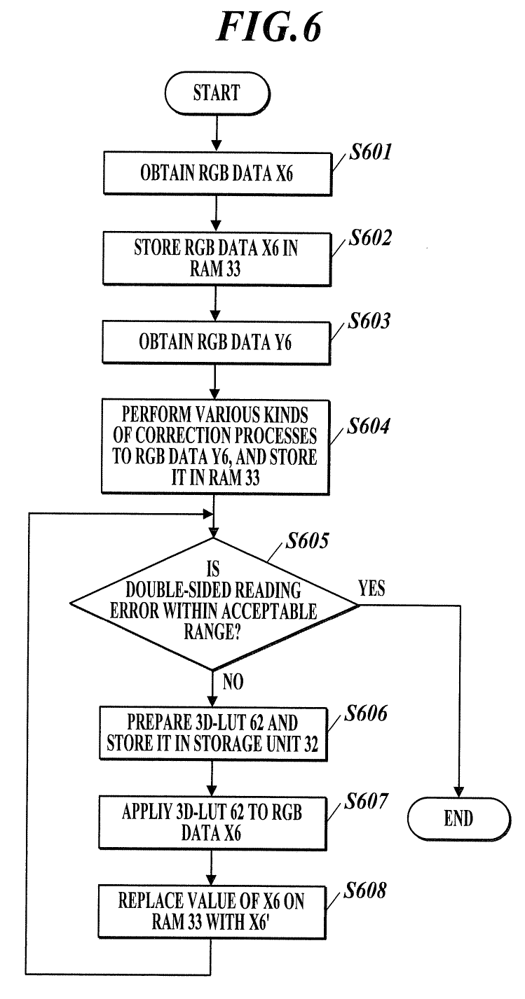

FIG. 6 shows the 3D-LUT decision process P4 to be performed by the color conversion processing unit 30.

The 3D-LUT decision process P4 is realized by a software process in cooperation with the control unit 31 and the program stored in the storage unit 32 when inputting a preparing instruction by the operation unit 40.

In the 3D-LUT decision process P4, the 3D-LUT 62 is determined to be used in step S503 of the 3D-LUT color conversion process P3.

First, the first reading unit 11 reads the document chart D, and RGB data X6 is obtained (step S601). Next, RGB data X6 is stored in the RAM 33 (step S602).

In the same manner, the second reading unit 12 reads the document chart D, RGB data Y6 is obtained (step S603). Next, an image process of the gamma correction, and so on for correcting color difference between colors represented by read data of the second reading unit 12 and colors of the document chart D is performed to RGB data Y6 and stored in the RAM 33 (step S604).

Sequentially, the differences (hereinafter referred to as double-sided reading error) between RGB data X6 and RGB data Y6 is compared with the predetermined acceptable values (step S605). The acceptable values are variable and inputted by the operation unit 40, and the values are stored in the storage unit 32.

When the double-sided reading error is not within the range of the acceptable value (step S605; No), the 3D-LUT 62 is prepared so that RGB data X6 approaches RGB data Y6, and stored in the storage unit 32 (step S606). Next, the 3D-LUT process is performed to RGB data X6 using 3D-LUT 62 prepared in step S606 (step S607). In step S604, a value(s) of RGB data X6 stored in the RAM 33 is replaced with RGB data X6′ obtained in step S607 (step S608), and the step moves to step S605.

The double-sided reading error is not more than the acceptable value (step S605; YES), the process is ended.

Thus, it is possible to obtain 3D-LUT 62 for correcting the difference of the reading characteristics of the first reading unit 11 and the second reading unit 12 by the 3D-LUT decision process P4. The 3D-LUT 62 is used in step S503 of the 3D-LUT color conversion process P3.

Also, in step S604, color difference between colors represented by read data of the first reading unit 12 and colors of the document chart D are corrected, the correction is performed using the 3D-LUT 62 prepared based on the corrected data. As a result, the problem of making color difference large in comparison with the document when one of the first reading unit and the second reading unit is matched with the other one is solved.

### Third Embodiment

Next, the third embodiment of the present invention will be described. In addition, since the components of the image reading apparatus 10 in the third embodiment is almost same with the components explained in the first embodiment, the explanations are incorporated, and different portions are explained below.

The storage unit 32 is different from the first embodiment because 3D-LUT 63 and 3D-LUT 64 to be used in a color conversion process mentioned later is stored. The 3D-LUT 63 and 3D-LUT 64 are tables for matching the reading characteristics of the first reading unit 11 and the reading characteristics of the second reading unit 12 to the reading characteristics of a flatbed respectively. The detailed explanations are mentioned later.

That is, 3D-LUT 63 and 3D-LUT 64 are color correction tables for correcting the error of the read color of the image read by the first reading unit 11 and the image read by the second reading unit 12 and a table for matching colors of the read image of the first surface of the document and colors of the read image of the second surface of the document.

Though the reading characteristics of the second reading unit 12 is matched to the reading characteristics of the first reading unit 11 in the first embodiment and the reading characteristics of the first reading unit 11 are matched to the reading characteristics of the second reading unit 12 in the second embodiment, the reading characteristics of the first reading unit 11 and the second reading unit 12 are matched to the reading characteristics of the flatbed in the third embodiment.

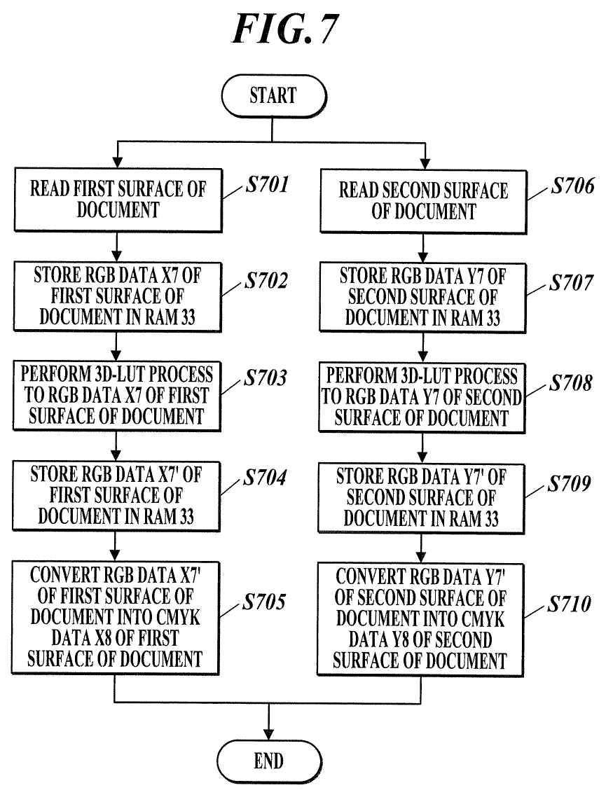

FIG. 7 schematically shows a flow of processes of the 3D-LUT color conversion process P5 to be performed by the color conversion processing unit 30. The first reading unit 11 reads the first surface of a document, and the second reading unit 12 reads a second surface of the document almost simultaneously with performing the color conversion process of the first surface of the document and performs the color conversion process of the second surface of the document.

The 3DLUT color conversion process P5 is realized by a software process in cooperation with the control unit 31 and the program stored in the storage unit 32 when inputting an image reading instruction by the operation unit 40.

In the 3D-LUT color conversion process P5, the correction for matching the reading characteristics of the first reading unit 11 and the second reading unit 12 to the reading characteristics of the flatbed is performed.

First, processes of read data of the first surface of the document read by the first reading unit 11 will be described. The first surface of the document is read by the first reading unit 11, and the first surface RGB data X7 of the document is obtained (step S701). Next, the first surface RGB data X7 of the document obtained in step S701 is stored in the RAM 33 (step S702).

The first surface RGB data X7 of the document is converted to the first surface RGB data X7′ of the document by 3D-LUT 63 prestored in the storage unit 32 (step S703), and stored in the RAM 33 (step S704). In addition, the 3D-LUT 63 to be used in step S703 is prepared by 3D-LUT decision process P6 mentioned later.

Sequentially, the first surface RGB data X7′ of the document is converted to the first surface CMYK data X8 by the 3D-LUT 60 prestored in the storage unit 32 (step S705).

Next, processes of read data of the second surface of the document read by the second reading unit 12 will be described. The processes explained below are performed almost simultaneously with the processes of the read data of the first surface of the document explained previously.

First, the second surface of the document is read by the second reading unit 12, second surface RGB data Y7 of the document is obtained (step S704). Next, the second surface RGB data Y7 of the document obtained in step S706 is stored in the RAM 33 (step S707).

The second surface RGB data Y7 of the document is converted to the second surface CMYK data Y7′ by 3D-LUT 64 prestored in the storage unit 32 (step S708), and stored in the RAM 33 (step S709).

In addition, the 3D-LUT 64 to be used in step S708 is prepared in the 3D-LUT decision process P6 mentioned later.

Then, the second surface RGB data Y7′ of the document is converted to the second surface CMYK data Y8 by the 3D-LUT 60 prestored in the storage unit 32 (step S710).

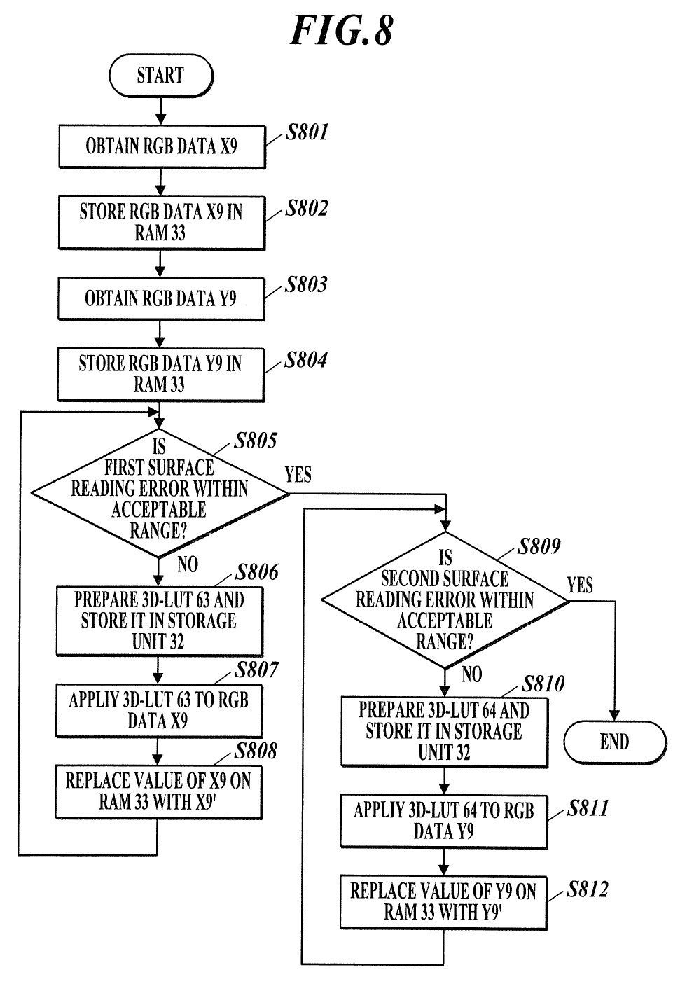

FIG. 8 shows the 3D-LUT decision process P6 to be performed by the color conversion processing unit 30.

The 3D-LUT decision process P6 is realized by a software process in cooperation with the control unit 31 and the program stored in the storage unit 32 when inputting a preparing instruction by the operation unit 40.

In the 3D-LUT decision process P6, the 3D-LUT 63 to be used in step S703 of color conversion process P5 and the 3D-LUT 64 to be used in step S708 are determined.

First, the first reading unit 11 reads the document chart D, and RGB data X9 is obtained (step S801). Next, RGB data X9 is stored in the RAM 33 (step S802).

In the same manner, the second reading unit 12 reads the document chart D, and RGB data Y9 is obtained (step S803). Next, RGB data Y9 is stored in the RAM 33 (step S804).

Sequentially, the differences (hereinafter referred to as first surface reading error) between RGB data X9 and RGB data X12 obtained by reading the document chart D by the flatbed are compared with the predetermined acceptable values (step S805). The acceptable values are variable and inputted by the operation unit 40, and the values are stored in the storage unit 32. In addition, RGB data X12 is prestored in the storage unit 32.

When the first surface reading error is not within the range of the acceptable value (step S805; No), the 3D-LUT 63 is prepared so that RGB data X9 approaches RGB data X12, and stored in the storage unit 32 (step S806). Next, the 3D-LUT process is performed to RGB data X9 using 3D-LUT 63 prepared in step S806 (step S807). The RGB data X9 stored in RAM 33 in step S802 is replaced with a value(s) of RGB data X9′ obtained in step S807 (step S808), and the step moves to step S805.

The first surface reading error is not more than the acceptable value (step S805; YES), the differences (hereinafter referred to as second surface reading error) between RGB data Y9 and the RGB data X12 are compared with the predetermined acceptable values (step S809). The acceptable values are variable and inputted by the operation unit 40, and the values are stored in the storage unit 32.

When the second surface reading error is not within the range of the acceptable value (step S809; No), the 3D-LUT 64 is prepared so that RGB data Y9 approaches RGB data X12, and stored in the storage unit 32 (step S810). Next, the 3D-LUT process is performed to RGB data Y9 using the 3D-LUT 64 prepared in step S810 (step S811). The RGB data Y9 stored in RAM 33 in step S804 is replaced with a value(s) of RGB data Y9′ obtained in step S811 (step S812), and the step moves to step S809.

The second surface reading error is not more than the acceptable value (step S809; YES), the process is ended.

Thus, it is possible to obtain 3D-LUT 63 and 3D-LUT 64 for matching the reading characteristics of the first reading unit 11 and the second reading unit 12 to the reading characteristics of the flatbed by the 3D-LUT decision process P6. It is possible to correct the reading characteristics of the first reading unit 11 and the second reading unit 12 using the 3D-LUT 63 and the 3D-LUT 64 by the 3D-LUT color conversion process P5.

In this embodiment, though the correction for matching the reading characteristics of the first reading unit 11 and the second reading unit 12 to the reading characteristics of the flatbed is performed, it is possible to match the reading characteristics of the first reading unit 11 and the second reading unit 12 to other common data. For example, it is considered that the reading characteristics of the first reading unit 11 and the second reading unit 12 are matched to common data of sRGB or Adobe, and so on.

Also, in the first embodiment to the third embodiment, the first reading unit 11 is composed of CCD, and so on, and the second reading unit is composed of CIS, and so on.

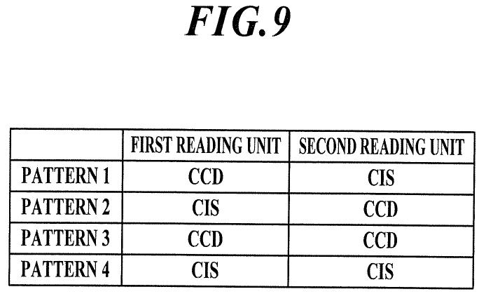

However, when the first reading unit 11 and the second reading unit 12 are made by same compositions, errors about the reading characteristics such as the difference of materials and assembly error and so on occur. Accordingly, it is possible to make compositions of the first reading unit 11 and the second reading unit 12 same. For example, The combination shown in FIG. 9 is considered.

Although various exemplary embodiments of the image reading apparatus 10 have been shown and described, the invention is not limited to the embodiments shown. Therefore, the scope of the invention is intended to be limited solely by the scope of the claims that follow.

The entire disclosure of Japanese Patent Applications No. 2007-285134 filed on Nov. 1, 2007 including specifications, claims, drawings and summaries are incorporated herein by reference in their entirety.

What is claimed is:

1. An image reading apparatus comprising:
a first reading unit for reading a first surface image of a document;
a second reading unit for reading a second surface image of the document; and
a color conversion processing unit for generating a table for correcting an error of a read color of an image read by the first reading unit and an image read by the second reading unit, and performing a color conversion to the image read by the first reading unit and/or the image read by the second reading unit using the table.

2. An image reading apparatus according to claim 1, wherein the color conversion processing unit generates a table for matching data read by the second reading unit to data read by the first reading unit based on the read data obtained by reading a chart for correction including a color gamut representable by the color converting processing unit by the first reading unit and the read data obtained by reading the chart for correction by the second reading unit, and performs the color conversion to the image read by the second reading unit based on the generated tale.

3. An image reading apparatus according to claim 1, wherein the color conversion processing unit generates a table for matching data read by the first reading unit to data read by the second reading unit based on the read data obtained by reading a chart for correction including a color gamut representable by the color converting processing unit by the first reading unit and the read data obtained by reading the chart for correction by the second reading unit, and performs the color conversion to the image read by the first reading unit based on the generated tale.

4. An image reading apparatus according to claim 1, wherein the color conversion processing unit generates a first table for the first reading unit based on the read data obtained by reading a chart for correction including a color gamut representable by the color converting processing unit by the first reading unit and the read data corresponding to the chart for correction, generates a second table for the second reading unit based on the read data obtained by reading the chart for correction by the second reading unit and the read data corresponding to the chart for correction, performs the color conversion to the image read by the first reading unit based on the first table, and performs the color conversion to the image read by the second reading unit based on the second table.

5. An image reading apparatus according to claim 1, wherein the table is a color correction table for correcting the error of the read color of the image read by the first reading unit and the image read by the second reading unit and a table for converting inputted RGB data to corrected RGB data.

6. An image reading apparatus according to claim 5, wherein the color conversion processing unit further includes a color conversion table for converting the corrected RGB data to YMCK data.

7. An image reading method in an image reading apparatus comprising a first reading unit for reading a first surface image of a document and a second reading unit for reading a second surface image of the document, the method comprising the steps of:
generating a table for correcting an error of a read color of an image read by the first reading unit and an image read by the second reading unit; and
performing a color conversion to the image read by the first reading unit and/or the image read by the second reading unit using the table.

8. An image reading method according to claim 7, wherein the image reading apparatus comprises an image reading unit for performing a centralized control of the image reading apparatus,
the generating step generates a table for matching data read by the second reading unit to data read by the first reading unit based on the read data obtained by reading a chart for correction including a color gamut representable by the color converting processing unit by the first reading unit and the read data obtained by reading the chart for correction by the second reading unit, and
the color conversion performing step performs the color conversion to the image read by the second reading unit based on the generated tale.

9. An image reading method according to claim 7, wherein the image reading apparatus comprises an image reading unit for performing a centralized control of the image reading apparatus,
the generating step generates a table for matching data read by the first reading unit to data read by the second reading unit based on the read data obtained by reading a chart for correction including a color gamut representable by the color converting processing unit by the first reading unit and the read data obtained by reading the chart for correction by the second reading unit, and
the color conversion performing step performs the color conversion to the image read by the first reading unit based on the generated tale.

10. An image reading method according to claim 7, wherein the image reading apparatus comprises an image reading unit for performing a centralized control of the image reading apparatus,
the generating step generates a first table for the first reading unit based on the read data obtained by reading a chart for correction including a color gamut representable by the color converting processing unit by the first reading unit and the read data corresponding to the chart for correction, generates a second table for the second reading unit based on the read data obtained by reading the chart for correction by the second reading unit and the read data corresponding to the chart for correction, and
the color conversion performing step performs the color conversion to the image read by the first reading unit based on the first table, and performs the color conversion to the image read by the second reading unit based on the second table.

11. An image reading method according to claim 7, wherein the table is a color correction table for correcting the error of the read color of the image read by the first reading unit and the image read by the second reading unit and a table for converting inputted RGB data to corrected RGB data.

12. An image reading method according to claim 11, wherein the image reading apparatus comprises an image reading unit for performing a centralized control of the image reading apparatus, wherein the color conversion processing unit further includes a color conversion table for converting the corrected RGB data to YMCK data.
